(19) United States
(12) Patent Application Publication
(10) Pub. No.: US 2021/0126024 A1
(43) Pub. Date: Apr. 29, 2021

(54) Manufacturing Method for Array Substrate and Array Substrate

(71) Applicant: CHENGDU CEC PANDA DISPLAY TECHNOLOGY CO., LTD., Chengdu City, Sichuan (CN)

(72) Inventors: Xiang LIU, Chengdu City, Sichuan (CN); Xuejun SUN, Chengdu City, Sichuan (CN); Guangsheng LI, Chengdu City, Sichuan (CN); Qun MA, Chengdu City, Sichuan (CN)

(73) Assignee: CHENGDU CEC PANDA DISPLAY TECHNOLOGY CO., LTD., Chengdu City, Sichuan (CN)

(21) Appl. No.: 16/758,430

(22) PCT Filed: Mar. 23, 2020
(86) PCT No.: PCT/CN2020/080722

§ 371 Date: Apr. 23, 2020

(30) Foreign Application Priority Data
Oct. 23, 2019 (CN) 201911013106.4

(51) Int. Cl. H01L 27/12; H01L 29/786; H01L 29/66

(52) U.S. Cl. CPC H01L 27/1288; H01L 27/1225; G02F 1/1368; H01L 29/66969; H01L 29/78693

(57) ABSTRACT

Provided is a manufacturing method for an array substrate and an array substrate. The manufacturing method for an array substrate comprises: depositing a gate metal layer, and carrying out a first pass of photolithography to form a gate; depositing a gate insulation layer, a first semiconductor layer, a second semiconductor layer, a first barrier layer, a second barrier layer and a source-drain metal layer in sequence, carrying out a second pass of photolithography to form an active island, meanwhile forming a source and a drain; depositing a passivation layer, and carrying out a third pass of photolithography to form a conductive via in the passivation layer on the drain; and depositing a transparent conductive layer, and carrying out a fourth pass of photolithography to form the transparent conductive layer into the pixel electrode and enable the pixel electrode to be communicated with the drain through the conductive via.

### CROSS-REFERENCE TO RELATED APPLICATION

The present disclosure claims the priority to the Chinese patent application with the filing number CN201911013106.4, filed on Oct. 23, 2019 with the China Patent Office, and entitled “Manufacturing Method for Array Substrate and Array Substrate”, which is incorporated herein by reference in entirety.

### TECHNICAL FIELD

The present disclosure relates to the technical field of liquid crystal display, in particular to a manufacturing method for an array substrate and an array substrate.

### BACKGROUND ART

With the development of display technology, flat panel display devices such as liquid crystal display (“LCD” for short), due to advantages such as high image quality, power saving, thin body and no radiation, are widely applied in various consumer electronic products such as mobile phones, televisions, personal digital assistants and notebook computers, and become mainstream in display devices. A liquid crystal display panel is generally comprised of an array substrate, a color filter substrate and a liquid crystal molecule layer sandwiched between the array substrate and the color filter substrate, wherein the array substrate and the color filter substrate are arranged opposite. The liquid crystal molecules can be controlled to rotate by applying a driving voltage between the array substrate and the color filter substrate, so that light of a backlight module is refracted out to generate an image.

A manufacturing method for an array substrate known to the applicant includes six passes of photolithography, including: a first step: depositing a metal layer on a glass base substrate, and carrying out a first pass of photolithography to form a gate; a second step, depositing a gate insulation layer and an indium gallium zinc oxide IGZO semiconductor layer in sequence, and carrying out a second pass of photolithography to form an active island pattern; a third step, depositing an etching barrier layer, and carrying out a third pass of photolithography; fourth step, depositing a source-drain metal layer, and carrying out a fourth pass of photolithography to form a source and a drain; a fifth step, depositing a passivation layer and a planarization layer, and carrying out a fifth pass of photolithography to form a conductive via; and a sixth step, depositing a transparent conductive film, and carrying out a sixth pass of photolithography to form a pixel electrode and a communication pattern of the conductive via and the pixel electrode.

The above manufacturing method for an array substrate, including six passes of photolithography, is complex in process, and high in manufacturing cost.

### SUMMARY

The present disclosure provides a manufacturing method for an array substrate and an array substrate, which only requires four passes of photolithography to realize the manufacturing of the array substrate, with simple process, and low manufacturing cost.

An embodiment of the present disclosure provides a manufacturing method for an array substrate, including:
manufacturing method for an array substrate, including:
depositing a gate metal layer on a base substrate, and carrying out a first pass of photolithography to form the gate metal layer into a gate;
depositing a gate insulation layer, a first semiconductor layer, a second semiconductor layer, a first barrier layer, a second barrier layer and a source-drain metal layer in sequence, carrying out a second pass of photolithography to form the first semiconductor layer and the second semiconductor layer into an active island, meanwhile forming the source-drain metal layer into a source and a drain, and forming the first barrier layer and the second barrier layer into double barrier layers located between the source and the second semiconductor layer and double barrier layers located between the drain and the second semiconductor layer;
depositing a passivation layer, and carrying out a third pass of photolithography to form a conductive via in the passivation layer on the drain; and
depositing a transparent conductive layer, and carrying out a fourth pass of photolithography to form the transparent conductive layer into the pixel electrode and enable the pixel electrode to be communicated with the drain through the conductive via.

Optionally, the second pass of photolithography includes one pass of gray-tone mask process or half-tone mask process.

Optionally, the second pass of photolithography includes:
forming, through exposure and development with the mask, a light fully-transmissive region, a light partially-transmissive region and a light non-transmissive region, wherein the light non-transmissive region corresponds to the source and the drain, the light partially-transmissive region corresponds to the channel region between the source and the drain, and the light fully-transmissive region corresponds to a region other than the light partially-transmissive region and the light non-transmissive region;
carrying out a first pass of etching to etch away the source-drain metal layer, the second barrier layer, the first barrier layer, the second semiconductor layer and the first semiconductor layer in the light fully-transmissive region;
carrying out one pass of ashing in the photolithography to remove a photo resist in the light partially-transmissive region; carrying out a second pass of etching to etch away the source-drain metal layer, the second barrier layer and the first barrier layer within the light partially-transmissive region, so as to form the channel region; and
reserving the source-drain metal layer within the light non-transmissive region, so as to form the source and the drain.

Optionally, the second pass of photolithography further includes:
etching away, when carrying out the second pass of etching, a part of the second semiconductor layer corresponding to the light partially-transmissive region, and reserving part of the first semiconductor layer corresponding to the light partially-transmissive region, so as to form the channel region.

Optionally, the second pass of photolithography further includes:
treating, after completing the second pass of etching, a surface of the first semiconductor layer within the channel region using nitrous oxide in one pass, so as to repair damage and address contamination to the first semiconductor layer caused by the second pass of etching.

Optionally, the first semiconductor layer and the second semiconductor layer are both metal oxide semiconductor layers, including amorphous indium gallium zinc oxide.

Optionally, an oxygen content of the first semiconductor layer is lower than an oxygen content of the second semiconductor layer.

Optionally, the first barrier layer is a titanium metal nitride, and the second barrier layer is titanium or titanium alloy.

Optionally, the first barrier layer has a thickness of 20-500 Å, and the second barrier layer has a thickness of 100-500 Å.

In the manufacturing method for an array substrate provided in embodiments of the present disclosure, a metal oxide thin film transistor structure is adopted, one pass of half-tone or gray-tone mask is used in the second pass of photolithography to simultaneously form the metal oxide semiconductor layer pattern, the source-drain metal electrode, the data line, the scan line and the channel region between the source and the drain, thus saving two times of photolithography, and improving the production efficiency; meanwhile, the double layers of metal oxide semiconductor layer structures are skillfully designed, the upper layer is the high-conductivity metal oxide semiconductor layer, the lower layer is the low-conductivity metal oxide semiconductor layer, at the same time, the double layers of barrier structures are designed, which prevents oxygen in the metal oxide semiconductor layer from diffusing to the outside, and fundamentally avoids the problem of oxygen loss in the metal oxide semiconductor layer. Such design can reduce the process difficulty, improve the stability and the performance of the thin film transistor. Further, before deposition of the passivation layer, the metal oxide semiconductor layer in the channel region is treated, to repair damage and address contamination caused to the metal oxide semiconductor layer when forming the channel region, thereby improving the performance of the thin film transistor.

An embodiment of the present disclosure further provides an array substrate, which is manufactured by the manufacturing method as above. The array substrate includes a base substrate, and a gate, a gate insulation layer, a first semiconductor layer, a second semiconductor layer, a first barrier layer, a second barrier layer, a source-drain layer (source-drain metal layer), a passivation layer and a pixel electrode disposed in sequence on the base substrate, the source-drain layer includes a source and a drain, and a channel region is between the source and the drain;
the first semiconductor layer and the second semiconductor layer are both metal oxide semiconductor layers, and an oxygen content of the first semiconductor layer is lower than an oxygen content of the second semiconductor layer;
the first barrier layer is titanium metal nitride, and the second barrier layer is titanium or titanium alloy; and
the passivation layer has a conductive via thereon, and the pixel electrode is communicated with the drain through the conductive via.

The array substrate provided in the embodiments of the present disclosure adopts the double metal oxide semiconductor layers and the double layers of barrier structures, the upper layer of metal oxide semiconductor layer is the metal oxide semiconductor layer with high conductivity, the lower layer of metal oxide semiconductor layer is the metal oxide semiconductor layer with low conductivity, the double layers of barrier structures can prevent oxygen in the metal oxide semiconductor from diffusing, can well protect the balance capability of oxygen in the metal oxide semiconductor layers. Such design enables the metal oxide semiconductor layers, the source-drain metal electrode, the data line and the channel region to be formed in the same pass of photolithography, thus saving two times of photolithography, reducing the process difficulty, and also improving the stability and the performance of the thin film transistor.

### BRIEF DESCRIPTION OF DRAWINGS

In order to more clearly illustrate technical solutions in the present disclosure or the prior art, accompanying drawings which need to be used for description of the embodiments or the prior art will be introduced briefly below, and apparently, the accompanying drawings in the description below merely show some embodiments of the present disclosure, and those ordinarily skilled in the art still could obtain other accompanying drawings in light of these accompanying drawings, without inventive effort.

FIG. 1 is a plan view of an array substrate provided in an embodiment of the present disclosure;

FIG. 2 is a flowchart of a manufacturing method for an array substrate provided in an embodiment of the present disclosure;

FIG. 3 is a structural schematic view of the array substrate provided in an embodiment of the present disclosure along an AB direction after a first pass of photolithography is completed;

FIG. 4 is a structural schematic view of the array substrate provided in an embodiment of the present disclosure along the AB direction after exposure and development in a second pass of photolithography is completed;

FIG. 5 is a structural schematic view of the array substrate provided in an embodiment of the present disclosure along the AB direction after a first pass of etching in the second pass of photolithography is completed;

FIG. 6 is a structural schematic view of the array substrate provided in an embodiment of the present disclosure along the AB direction after ashing in the second pass of photolithography is completed;

FIG. 7 is a structural schematic view of the array substrate provided in an embodiment of the present disclosure along the AB direction after the second pass of photolithography is completed;

FIG. 8 is a structural schematic view of the array substrate provided in an embodiment of the present disclosure along the AB direction after a third pass of photolithography is completed; and

FIG. 9 is a structural schematic view of the array substrate provided in an embodiment of the present disclosure along the AB direction after a fourth pass of photolithography is completed.

### REFERENCE SIGNS

11—base substrate;

12—gate;

13—gate insulation layer;

141—first semiconductor layer;

142—second semiconductor layer;

151—first barrier layer;

152—second barrier layer;

16—source-drain metal layer;

161—source;

162—drain;

17—photo resist;

18—light fully-transmissive region;

19—light non-transmissive region;

20—light partially-transmissive region;

21—channel region;

22—passivation layer;

23—conductive via;

24—pixel electrode;

25—scan line;

26—data line.

### DETAILED DESCRIPTION OF EMBODIMENTS

In order to make objects, technical solutions and advantages of the present disclosure clearer, the technical solutions in the present disclosure will be described clearly and completely below in conjunction with the accompanying drawings in the present disclosure, and apparently, some but not all embodiments of the present disclosure are described. Based on the embodiments of the present disclosure, all other embodiments obtained by those ordinarily skilled in the art without inventive effort shall fall within the scope of protection of the present disclosure.

It should be understood that, a conventional liquid crystal display panel is formed by attaching one thin film transistor array substrate (“TFT Array Substrate” for short) and one color filter substrate (“CF Substrate” for short), a pixel electrode and a common electrode are formed on the array substrate and the color filter substrate, respectively, and liquid crystal is injected between the array substrate and the color filter substrate. The working principle of the conventional liquid crystal display panel is that, by applying a driving voltage between the pixel electrode and the common electrode, liquid crystal molecules inside the liquid crystal layer are controlled to rotate by an electric field formed between the pixel electrode and the common electrode, so that light of a backlight module is refracted out to generate an image.

Mask, also called as photo mask, is a master pattern mask used in photolithography, wherein a mask pattern is formed on a transparent base substrate by means of a light non-transmissive shading thin film (metal chromium), and the pattern is transferred onto a thin film of the glass base substrate through photolithography. The exposure process is a process of transferring the pattern on the mask onto the photo resist by irradiating the photo resist with ultraviolet through the mask. In array engineering, the photo functions as a mask. In an etching process, a thin film layer on a substrate corresponding to a photo resist pattern is reserved by exposing the photo resist pattern formed, other areas are etched away, finally the photo resist is removed, then the pattern on the mask is transferred onto the substrate, which process is called as photolithography. Each photolithography process includes process steps of thin film deposition, photo resist coating, exposure, development, etching and photo resist stripping.

It can be understood that the number of steps of the photolithography affects both the yield of the panels, and the manufacturing cost of the panels, therefore, the times of photolithography is preferably as few as possible.

The present disclosure is described below with reference to accompanying drawings in combination with specific embodiments.

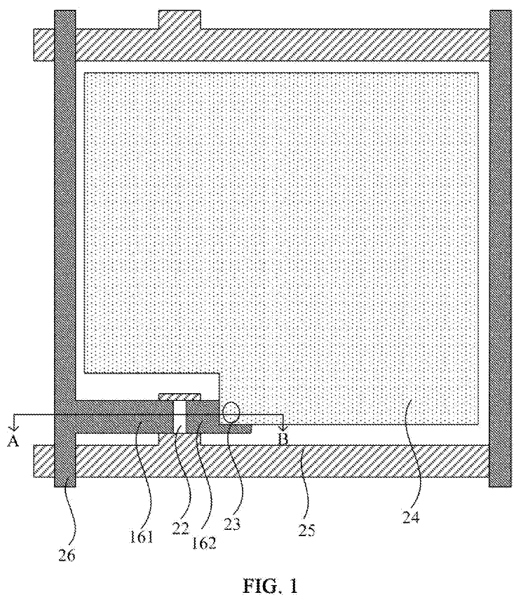

FIG. 1 is a plan view of an array substrate provided in an embodiment of the present disclosure. Referring to what is shown in FIG. 1, an array substrate provided in an embodiment of the present disclosure may include a source 161, a drain 162, a passivation layer 22, a conductive via 23, a pixel electrode 24, a scan line 25 and a data line 26, wherein the pixel electrode 24 can be communicated with the drain 162 through the conductive via 23, the scan line 25 can be communicated with a gate 12 and both the scan line and the gate can be formed in the same photolithography, and the data line 26 can be communicated with the source 161 and both the data line and the source can be formed in the same photolithography. It should be noted that FIG. 1 is a plan view of the array substrate, and due to angle of the view, part of the structure of the array substrate is not shown in FIG. 1, and therefore is not introduced herein.

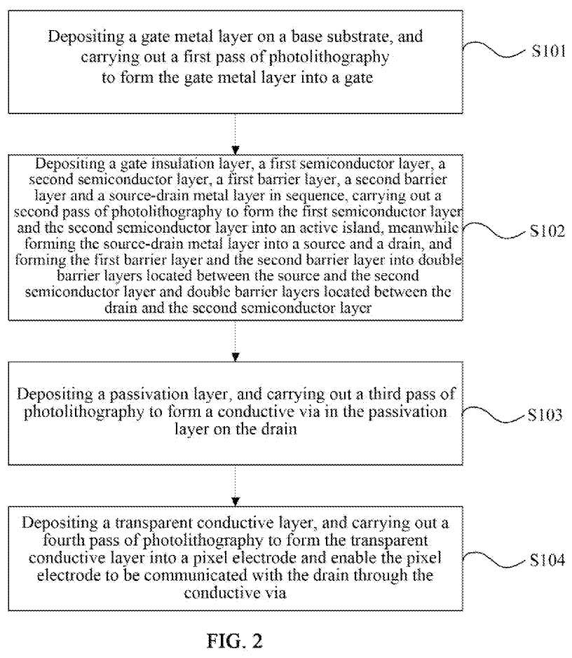

FIG. 2 is a flowchart of a manufacturing method for an array substrate provided in an embodiment of the present disclosure, and as shown in FIG. 2, the manufacturing method for an array substrate provided in an embodiment of the present disclosure may include:

S101: depositing a gate metal layer on a base substrate 11, and carrying out a first pass of photolithography to form the gate metal layer into a gate 12.

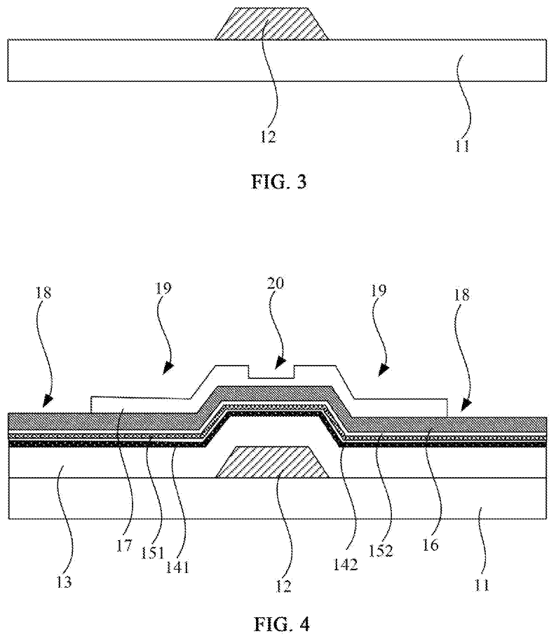

Specifically, the gate metal layer with a thickness of about 500-4000 Å can be deposited on the base substrate 11 by a method of sputtering or thermal evaporation, the gate metal layer may be made from metals such as Cr, W, Ti, Ta, Mo, Al, and Cu or alloys thereof, and a gate metal layer composed of multiple layers of metal also can meet the requirement. FIG. 3 is a structural schematic view of the array substrate provided in an embodiment of the present disclosure along an AB direction after the first pass of photolithography is completed, and as shown in FIG. 3, the gate metal layer is formed into a gate 12 through the first pass of photolithography.

S102: depositing a gate insulation layer 13, a first semiconductor layer 141, a second semiconductor layer 142, a first barrier layer 151, a second barrier layer 152 and a source-drain metal layer 16 in sequence, carrying out a second pass of photolithography to form the first semiconductor layer 141 and the second semiconductor layer 142 into an active island, meanwhile forming the source-drain metal layer 16 into a source 161 and a drain 162, and forming the first barrier layer 151 and the second barrier layer 152 into double barrier layers located between the source 161 and the second semiconductor layer 142 and double barrier layers located between the drain 162 and the second semiconductor layer 142.

Specifically, the gate insulation layer 13 having a thickness of 2000-5000 Å can be continuously deposited by a plasma enhanced chemical vapor deposition (PECVD) method on the base substrate 11 having undergone S101, the gate insulation layer 13 can be made from an oxide, a nitride or an oxynitride, and a corresponding reaction gas may be SiH₄, NH₃ or N₂ or SiH₂C₁₂, NH₃ or N₂.

The first semiconductor layer 141 having a thickness of 50-2000 Å and a second semiconductor layer 142 having a thickness of 50-2000 Å are successively deposited by a sputtering method, the first semiconductor layer 141 and the second semiconductor layer 142 both are metal oxide semiconductors, the first semiconductor layer 141 and the second semiconductor layer 142 may be made from amorphous indium gallium zinc oxide IGZO, HIZO, IZO, a-InZnO, ZnO:F, In₂O₃:Sn, In₂O₃:Mo, Cd₂SnO₄, ZnO:Al, TiO₂:Nb, Cd—Sn—O or other metal oxides; the conductivity of the metal oxide semiconductor can be effectively controlled by controlling a content of oxygen during deposition of the metal oxide semiconductor layer, if the deposited metal oxide semiconductor layer film has a high content of oxygen, the metal oxide semiconductor film has good conductivity, and almost becomes a conductor; if the deposited metal oxide semiconductor layer film has a low content of oxygen, the metal oxide semiconductor film has poor conductivity, and becomes a semiconductive conductor; by controlling the oxygen content in the first semiconductor layer 141 and the second semiconductor layer 142, the first semiconductor layer 141 is enabled to have a low content of oxygen, and becomes a metal oxide semiconductor layer with a low oxygen content, meanwhile, the second semiconductor layer 142 is enabled to have a high content of oxygen, and becomes a metal oxide semiconductor layer with a high oxygen content, thus, the first semiconductor layer 141 has low conductivity, and the second semiconductor layer 142 has high conductivity; the low-conductivity first semiconductor layer 141 directly contacts the gate insulation layer 13, and located in a channel region 21 between the source and the drain, such that the thin film transistor has more stable performance, the high-conductivity second semiconductor layer 142 contacts the barrier layer 151, the first barrier layer 151 contacts the second barrier layer 152, and the second barrier layer 152 contacts the drain 161 and the source 162, thereby contact resistance between the metal oxide semiconductor layer and the source and drain can be reduced, and an on-state current of the metal oxide thin film transistor is increased.

Next, the first barrier layer 151 having a thickness of about 20-500 Å, the second barrier layer 152 having a thickness of about 100-500 Å and the source-drain metal layer 16 having a thickness of about 1500-5000 Å can be deposited successively by sputtering or thermal evaporation. The first barrier layer 151 may be a titanium metal nitride TiNX. TiN_{X} is a vacancy-type solid solution having a wider composition range, and has a stable range of TiN_{0.37}-TiN_{1.2}, wherein it is an N-vacancy solid solution when N content is lower, and generally exhibits more metallic properties, and it is a Ti-vacancy solid solution when Ti content is lower, and exhibits more covalent compound properties. The second barrier layer 152 is titanium or titanium alloy, and the source-drain metal layer 16 is Cu, wherein TiN_{X} has a good barrier capability to oxygen, and can prevent oxygen in the metal oxide semiconductor layer from diffusing to the outside or being taken by outside titanium, so that the balance capability of oxygen in the metal oxide semiconductor layer can be well protected, and the first barrier layer TiN_{X} can further prevent diffusion of Cu ions.

Specifically, the second pass of photolithography can be carried out by a half-tone mask process or one pass of gray-tone mask process. In the above, the half-tone mask (“HTM” for short) process is a process of incompletely exposing a light resistor using a semi-transparent film on the mask. The gray-tone mask process is a process of incompletely exposing a light resistor using a light blocking strip in a gray scale region on the mask.

The second pass of photolithography may include following processes:
after exposure and development with the mask, as shown in FIG. 4—which is a structural schematic view of the array substrate provided in an embodiment of the present disclosure along the AB direction having undergone the exposure and development in the second pass of photolithography—forming a light fully-transmissive region 18, a light non-transmissive region 19 and a light partially-transmissive region 20, wherein the light non-transmissive region 19 corresponds to the source, the drain and the data line 26, the light partially-transmissive region 20 corresponds to the channel region 21 between the source and the drain, and the light fully-transmissive region 18 corresponds to a region other than the light non-transmissive region 19 and the light partially-transmissive region 20. The light partially-transmissive region 20 is located between the two light non-transmissive regions 19, and the two light fully-transmissive regions 18 are located at two sides of the two light non-transmissive regions 19, respectively.

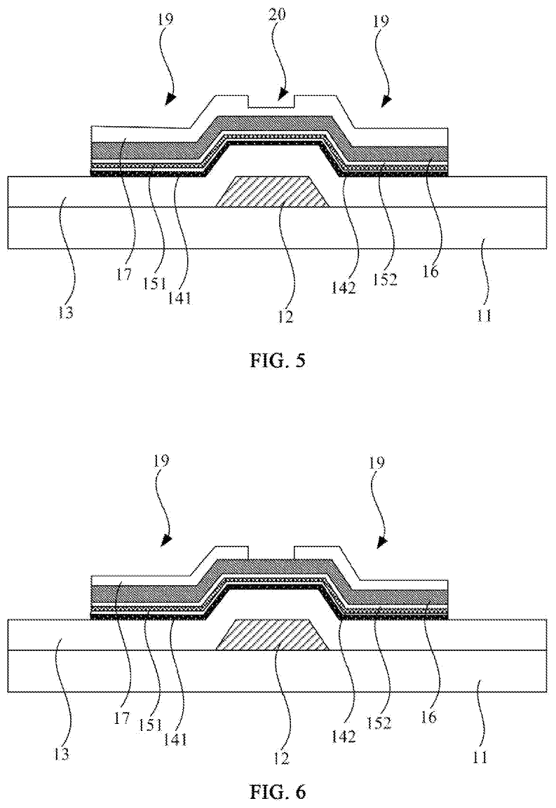

Next, a first pass of etching is carried out, as shown in FIG. 5—which is a structural schematic view of the array substrate provided in an embodiment of the present disclosure along the AB direction after having undergone the first pass of etching in the second pass of photolithography—to remove the source-drain metal layer 16, the second barrier layer 152, the first barrier layer 151, the second semiconductor layer 142 and the first semiconductor layer 141 within the light fully-transmissive region 18 through the etching process.

Next, one pass of ashing in the photolithography is carried out, as shown in FIG. 6—which is a structural schematic view of the array substrate provided in an embodiment of the present disclosure along the AB direction after having undergone the ashing in the second pass of photolithography—to remove a photo resist 17 within the light partially-transmissive region 20.

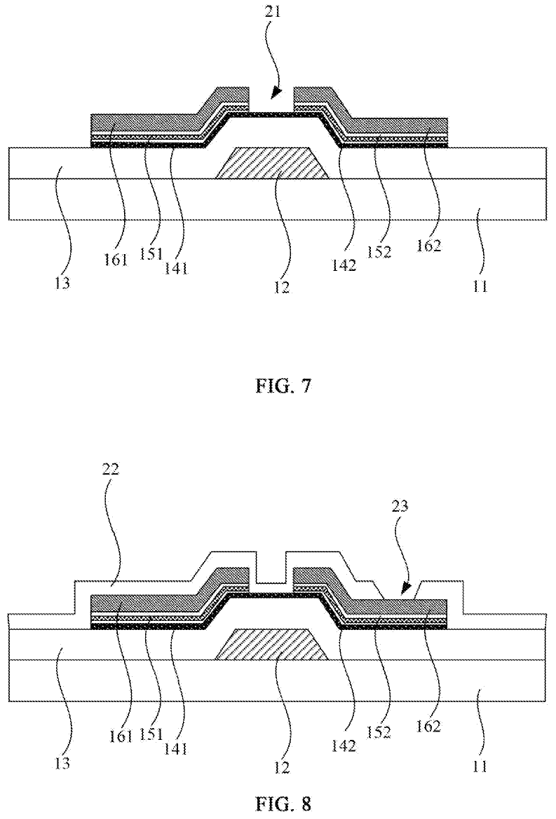

Next, a second pass of etching is carried out, as shown in FIG. 7—which is a structural schematic view of the array substrate provided in an embodiment of the present disclosure along the AB direction after having undergone the second pass of photolithography—to etch away the source-drain metal layer 16, the second barrier layer 152, and the first barrier layer 151 within the light partially-transmissive region 20 through the etching process, so as to form the channel region 21 between the source and the drain, wherein the source-drain metal layer 16 that is not etched away on the left side forms the source 161, and the source-drain metal layer 16 that is not etched away on the right side forms the drain 162.

Preferably, in the second pass of photolithography, when the second pass of etching is carried out, all of the second semiconductor layer 142 located within the light partially-transmissive region 20 is etched away, while the source-drain metal layer 16, the second barrier layer 152 and the first barrier layer 151 within the light partially-transmissive region 20 are etched, by controlling the etching process, so as to form the channel region 21 between the source and the drain. In order to improve the performance of the thin film transistor, a surface of the first semiconductor layer 141 within the channel region 21 is further processed in one pass, for example, treated with N₂O to repair damage and address contamination to the first semiconductor layer 141 caused during the second pass of etching. Specifically, nitrous oxide gas is introduced into a reactor, and then plasma is generated inside the reactor, to remove most of organic compounds, thereby achieving the purpose of repairing the first semiconductor layer 141. The step of removing the organic compounds is also referred to as an “etch-back” process.

S103: depositing a passivation layer 22, and carrying out a third pass of photolithography to form a conductive via 23 in the passivation layer 22 on the drain 162.

FIG. 8 is a structural schematic view of the array substrate provided in an embodiment of the present disclosure along the AB direction after a third pass of photolithography is completed. As shown in FIG. 8, specifically, the passivation layer 22 having a thickness of 2000-5000 Å is continuously deposited by a plasma enhanced chemical vapor deposition method on the base substrate 11 having undergone S102, wherein the passivation layer 22 can be made from an oxide, a nitride or an oxynitride, there may be a single passivation layer or multiple passivation layers, and a corresponding reaction gas may be SiH₄, NH₃ or N₂ or SiH₂C₁₂, NH₃ or N₂. Through the third pass of photolithography, a passivation layer pattern having the conductive via 23 is formed, and the conductive via 23 is located on the drain 162.

S104: depositing a transparent conductive layer, and carrying out a fourth pass of photolithography to form the transparent conductive layer into the pixel electrode 24 and enable the pixel electrode 24 to be communicated with the drain 162 through the conductive via 23.

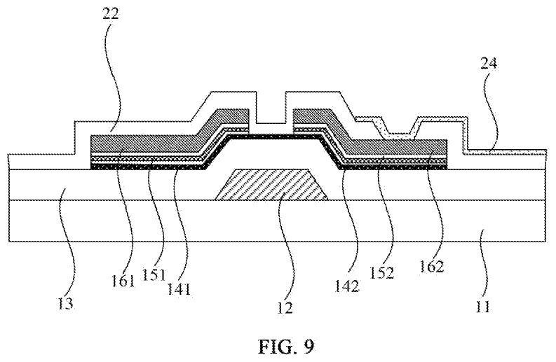

FIG. 9 is a structural schematic view of the array substrate provided in an embodiment of the present disclosure along the AB direction after a fourth pass of photolithography is completed, and as shown in FIG. 9, specifically, a transparent conductive layer having a thickness of about 300-1500 Å is continuously deposited by a method of sputtering or thermal evaporation on the base substrate 11 having undergone step S103, wherein the transparent conductive layer may be made from indium tin oxide ITO or indium zinc oxide IZO, or other transparent metal oxides. Through the fourth pass of photolithography, the transparent conductive layer is formed into the pixel electrode 24, and the pixel electrode 24 is enabled to be communicated with the drain 162 through the conductive via 23.

In the manufacturing method for an array substrate provided in the embodiments of the present disclosure, a metal oxide thin film transistor structure is adopted, one pass of half-tone or gray-tone mask is used in the second pass of photolithography to simultaneously form the metal oxide semiconductor layer pattern, the source-drain metal electrode, the data line, the scan line and the channel region between the source and the drain, thus saving two times of photolithography, and improving the production efficiency; meanwhile, the double layers of metal oxide semiconductor layer structures and the double layers of barrier structures are skillfully designed, the upper layer of metal oxide semiconductor layer is a high-conductivity metal oxide semiconductor and directly contacts with the source and the drain, thereby increasing the on-state current of the thin film transistor, the lower layer of metal oxide semiconductor layer is a low-conductivity semiconductor and directly contacts the gate insulation layer, which is located in the channel region between the source and the drain, thereby improving the performance of the thin film transistor; the double layers of barrier structures can prevent oxygen in the metal oxide semiconductor layer from diffusing outwards or being taken by external Ti or Cu, protecting the balance capacity of oxygen in the metal oxide semiconductor layer. Such design can reduce the process difficulty, improve the stability and the performance of the thin film transistor, and on the other hand, the metal oxide semiconductor layer in the channel region is treated before deposition of the passivation layer, to repair damage and address contamination to the metal oxide semiconductor layer caused when forming the channel region, thereby further improving the performance of the thin film transistor.

An embodiment of the present disclosure further provides an array substrate, which is manufactured by the above method, and as shown in FIG. 1 and FIG. 9, the array substrate may include: a base substrate 11, and a gate 12, a gate insulation layer 13, a first semiconductor layer 141, a second semiconductor layer 142, a first barrier layer 151, a second barrier layer 152, a source-drain metal layer, a passivation layer 22 and a pixel electrode 24 disposed in sequence on the base substrate 11, wherein the source-drain metal layer may include: a source 161, a drain 162, and a channel region 21 between the source 161 and the drain 162, wherein the first semiconductor layer 141 is a metal oxide semiconductor with a low oxygen content, and the second semiconductor layer 142 is metal oxide semiconductor with a high oxygen content; the passivation layer 22 has a conductive via 23 thereon, and the pixel electrode 24 is communicated with the drain 162 through the conductive via 23. This array substrate further may include a scan line 25 and a data line 26, the scan line 25 can be communicated with the gate 12 and both the scan line and the gate are formed in the same photolithography, and the data line 26 can be communicated with the source 161 and both the data line and the source can be formed in the same photolithography.

In the above, the gate 12 may have a thickness of about 500-4000 Å, and the gate may be made from metals such as Cr, W, Ti, Ta, Mo, Al, and Cu or alloys thereof, and a gate metal layer composed of multiple layers of metal also can meet the requirement.

The gate insulation layer 13 may have a thickness of 2000-5000 Å, the gate insulation layer may be made from an oxide, a nitride or an oxynitride, and a corresponding reaction gas may be SiH₄, NH₃ or N₂ or SiH₂C₁₂, NH₃ or N₂.

The first semiconductor layer 141 may have a thickness of 50-2000 Å, the second semiconductor layer 142 may have a thickness of 50-2000 Å, the first semiconductor layer 141 and the second semiconductor layer 142 both can be metal oxide semiconductors, the first semiconductor layer 141 and the second semiconductor layer 142 may be made from amorphous indium gallium zinc oxide IGZO, HIZO, IZO, a-InZnO, ZnO:F, In₂O₃:Sn, In₂O₃:Mo, Cd₂SnO₄, ZnO:Al, TiO₂:Nb, Cd—Sn—O or other metal oxides; the conductivity of the metal oxide semiconductor can be effectively controlled by controlling the content of oxygen during deposition of the metal oxide semiconductor layer, if the deposited metal oxide semiconductor layer film has a high content of oxygen, the metal oxide semiconductor film has good conductivity, and almost becomes a conductor; if the deposited metal oxide semiconductor layer film has a low content of oxygen, the metal oxide semiconductor film has poor conductivity, and becomes a semiconductive conductor; by controlling the content of oxygen when depositing the first semiconductor layer 141 and the second semiconductor layer 142, the first semiconductor layer 141 is enabled to have a low content of oxygen, and becomes a metal oxide semiconductor layer with a low oxygen content, meanwhile, the second semiconductor layer 142 is enabled to have a high content of oxygen, and becomes a metal oxide semiconductor layer with a high oxygen content, thus, the first semiconductor layer 141 has low conductivity, and the second semiconductor layer 142 has high conductivity; the low-conductivity first semiconductor layer 141 directly contacts the gate insulation layer 13, and located in the channel region 21 of the metal oxide semiconductor layer 14 between the source 161 and the drain 162 of the thin film transistor, such that the thin film transistor has more stable performance, the high-conductivity second semiconductor layer 142 contacts the barrier layer 151, the first barrier layer 151 contacts the second barrier layer 152, and the second barrier layer 152 contacts the drain 161 and the source 162, thereby contact resistance between the metal oxide semiconductor layer and the source and drain can be reduced, and an on-state current of the metal oxide thin film transistor is increased.

The first barrier layer 151 may have a thickness of about 20-500 Å, the second barrier layer 152 may have a thickness of 100-500 Å, and the source-drain metal layer 16 may have a thickness of 1500-5000 Å. The first barrier layer 151 may be titanium metal nitride TiNX, the second barrier layer 152 may be metal titanium Ti or titanium alloy, the source-drain metal layer 16 may be metal copper Cu, wherein TiN_{X} has good blocking capability to oxygen, and can prevent oxygen in the metal oxide semiconductor layer from diffusing to the outside or being taken by external titanium, and can well protect the balance capacity of oxygen in the metal oxide semiconductor layer.

The passivation layer 22 may have a thickness of 2000-5000 Å, the passivation layer may be made from an oxide, a nitride or an oxynitride, there may be a single passivation layer or multiple passivation layers, and a corresponding reaction gas may be SiH₄, NH₃ or N₂ or SiH₂C₁₂, NH₃ or N₂.

The array substrate provided in an embodiment of the present disclosure adopts the double metal oxide semiconductor layers and the double layers of barrier structures, the upper layer of metal oxide semiconductor layer is the metal oxide semiconductor layer with high conductivity, the lower layer of metal oxide semiconductor layer is the metal oxide semiconductor layer with low conductivity, the double layers of barrier structures can prevent oxygen in the metal oxide semiconductor from diffusing, can well protect the balance capability of oxygen in the metal oxide semiconductor layers. Such design enables the metal oxide semiconductor layers, the source-drain metal electrode, the data line and the channel region to be formed in the same pass of photolithography, thus saving two times of photolithography, reducing the process difficulty, and also improving the stability and the performance of the thin film transistor.

In the description of the present disclosure, it should be understood that orientational or positional relations indicated with use of terms “center”, “length, “width”, “thickness”, “top end”, “bottom end”, “upper”, “lower”, “left”, “right”, “front”, “back”, “vertical”, “horizontal”, “inner”, “outer”, “axial”, “circumferential” and so on are based on orientational or positional relations as shown in the accompanying drawings, merely for facilitating the description of the present disclosure and simplifying the description, rather than indicating or implying that related position or elements have to be in the specific orientation, or specifically configured and operated, therefore, they should not be construed as limitation on the present disclosure.

Besides, terms “first” and “second” are merely used for descriptive purpose, but should not be construed as indicating or implying importance in the relativity or suggesting the number of a related technical feature. Thus, a feature defined with “first” or “second” may explicitly or implicitly mean that one or more such features are included. In the description of the present disclosure, “multiple (a plurality of)” means at least two, for example, two or three, unless otherwise defined explicitly.

In the present disclosure, unless otherwise specified and defined explicitly, terms such as “mount”, “join”, “connect” and “fix” should be construed in a broad sense. For example, it may be fixed connection, detachable connection, or integral connection; it may be mechanical connection, and also may be electrical connection or may be communicated with each other; it may be direct connection, indirect connection through an intermediate medium, or inner communication between two elements or interaction between two elements. For those ordinarily skilled in the art, specific meanings of the above-mentioned terms in the present disclosure can be understood according to specific circumstances.

In the present disclosure, unless otherwise specified and defined explicitly, a first feature being “above” or “below” a second feature may include the first feature and the second feature being in direct contact, and also may include the first feature and the second feature being not in direct contact but being in contact through another feature therebetween. Moreover, the first feature being “on”, “above” or “over” the second feature includes the first feature being right above or not right above the second feature, or merely means the level of the first feature being higher than that of the second feature. The first feature being “under”, “below” or “beneath” the second feature includes the first feature being directly below or not directly below the second feature, or merely means the level of the first feature being lower than that of the second feature.

Finally, it should be explained that various embodiments above are merely used for illustrating the technical solutions of the present disclosure, rather than limiting the present disclosure; while the detailed description is made to the present disclosure with reference to various preceding embodiments, those ordinarily skilled in the art should understand that they still could modify the technical solutions recited in various preceding embodiments, or make equivalent substitutions to some or all of the technical features therein; these modifications or substitutions do not make the corresponding technical solutions essentially depart from the scope of the technical solutions of various embodiments of the present disclosure.

### INDUSTRIAL APPLICABILITY

In the manufacturing method for an array substrate and the array substrate manufactured thereby provided in the embodiments of the present disclosure, the metal oxide thin film transistor structure is adopted, one pass of half-tone or gray-tone mask is used in the second pass of photolithography to simultaneously form the metal oxide semiconductor layer pattern, the source-drain metal electrode, the data line, the scan line and the channel region between the source and the drain, that is, enabling the metal oxide semiconductor layer, the source-drain metal electrode, the data line and the channel region to be formed in the same pass of photolithography, saving two times of photolithography, and improving the production efficiency; meanwhile, the double layers of metal oxide semiconductor layer structures are skillfully designed, the upper layer is the high-conductivity metal oxide semiconductor layer, the lower layer is the low-conductivity metal oxide semiconductor layer, at the same time, the double layers of barrier structures are designed, which can prevent oxygen in the metal oxide semiconductor from diffusing—optionally, preventing oxygen in the metal oxide semiconductor layers from diffusing to the outside, thus, the balance capacity of oxygen in the metal oxide semiconductor layer can be well protected, and the problem of oxygen loss in the metal oxide semiconductor layer can be fundamentally avoided. Such design can reduce the process difficulty, improve the stability and the performance of the thin film transistor. Further, before deposition of the passivation layer, the metal oxide semiconductor layer in the channel region is treated, to repair damage and address contamination caused to the metal oxide semiconductor layer when forming the channel region, thereby improving the performance of the thin film transistor; on the other hand, before deposition of the passivation layer, the metal oxide semiconductor layer in the channel region is treated, to repair damage and address contamination caused to the metal oxide semiconductor layer when forming the channel region, further improving the performance of the thin film transistor.

1. A manufacturing method for an array substrate, comprising:
depositing a gate metal layer on a base substrate, and carrying out a first pass of photolithography to form the gate metal layer into a gate;
depositing a gate insulation layer, a first semiconductor layer, a second semiconductor layer, a first barrier layer, a second barrier layer and a source-drain metal layer in sequence on the base substrate provided with the gate, carrying out a second pass of photolithography to form the first semiconductor layer and the second semiconductor layer into an active island, meanwhile forming the source-drain metal layer into a source and a drain, and forming the first barrier layer and the second barrier layer into double barrier layers located between the source and the second semiconductor layer and double barrier layers located between the drain and the second semiconductor layer;
depositing a passivation layer, and carrying out a third pass of photolithography to form a conductive via in the passivation layer on the drain; and
depositing a transparent conductive layer, and carrying out a fourth pass of photolithography to form the transparent conductive layer into a pixel electrode and enable the pixel electrode to be communicated with the drain through the conductive via.

2. The manufacturing method according to claim 1, wherein the second pass of photolithography comprises one pass of gray-tone mask process or half-tone mask process.

3. The manufacturing method according to claim 2, wherein the second pass of photolithography comprises:
forming, through exposure and development with the mask, light fully-transmissive regions, a light partially-transmissive region and light non-transmissive regions, wherein the light non-transmissive regions corresponds to the source and the drain, respectively, the light partially-transmissive region corresponds to a channel region between the source and the drain, and the light fully-transmissive regions corresponds to regions other than the light partially-transmissive region and the light non-transmissive regions;
carrying out a first pass of etching to etch away the source-drain metal layer, the second barrier layer, the first barrier layer, the second semiconductor layer and the first semiconductor layer in the light fully-transmissive regions;
carrying out one pass of ashing in the photolithography to remove a photo resist in the light partially-transmissive region; carrying out a second pass of etching to etch away the source-drain metal layer, the second barrier layer and the first barrier layer within the light partially-transmissive region, so as to form the channel region; and
reserving the source-drain metal layer within the light non-transmissive regions, so as to form the source and the drain.

4. The manufacturing method according to claim 2, wherein the second pass of photolithography comprises:
forming, through exposure and development with the mask, light fully-transmissive regions, a light partially-transmissive region and light non-transmissive regions, wherein the light non-transmissive regions corresponds to the source and the drain, respectively, the light partially-transmissive region corresponds to a channel region between the source and the drain, and the light fully-transmissive regions corresponds to regions other than the light partially-transmissive region and the light non-transmissive regions;
carrying out a first pass of etching to etch away the source-drain metal layer, the second barrier layer, the first barrier layer, the second semiconductor layer and the first semiconductor layer in the light fully-transmissive regions;
carrying out one pass of ashing in the photolithography to remove a photo resist in the light partially-transmissive region; carrying out a second pass of etching to etch away the source-drain metal layer, the second barrier layer and the first barrier layer within the light partially-transmissive region, to etch away a part of the second semiconductor layer corresponding to the light partially-transmissive region, and to reserve a part of the first semiconductor layer corresponding to the light partially-transmissive region, so as to form the channel region; and
reserving the source-drain metal layer within the light non-transmissive regions, so as to form the source and the drain.

5. The manufacturing method according to claim 4, wherein the second pass of photolithography further comprises:
treating, after completing the second pass of etching, a surface of the first semiconductor layer within the channel region using nitrous oxide in one pass, so as to repair damage and address contamination to the first semiconductor layer caused by the second pass of etching.

6. The manufacturing method according to claim 1, wherein each of the first semiconductor layer and the second semiconductor layer is a metal oxide semiconductor layer, comprising amorphous indium gallium zinc oxide.

7. The manufacturing method according to claim 6, wherein an oxygen content of the first semiconductor layer is lower than an oxygen content of the second semiconductor layer.

8. The manufacturing method according to claim 1, wherein the first barrier layer is made from a titanium metal nitride, and the second barrier layer is made from titanium or titanium alloy.

9. The manufacturing method according to claim 8, wherein the first barrier layer has a thickness of 20-500 Å, and the second barrier layer has a thickness of 100-500 Å.

10. The manufacturing method according to claim 1, wherein the gate metal layer has a thickness of about 500-4000 Å, the gate metal layer is made from Cr, W, Ti, Ta, Mo, Al, Cu or alloys thereof, and the gate metal layer is in a form of a single layer or multiple layers.

11. The manufacturing method according to claim 1, wherein the gate insulation layer has a thickness of 2000-5000 Å, and the gate insulation layer is made from an oxide, a nitride or an oxynitride.

12. The manufacturing method according to claim 1, wherein the first semiconductor layer has a thickness of 50-2000 Å, the second semiconductor layer has a thickness of 50-2000 Å, and each of the first semiconductor layer and the second semiconductor layer is independently made from IGZO, HIZO, IZO, a-InZnO, ZnO:F, In₂O₃:Sn, In₂O₃:Mo, Cd₂SnO₄, ZnO:Al, TiO₂:Nb, or Cd—Sn—O.

13. The manufacturing method according to claim 1, wherein the source-drain metal layer has a thickness of 1500-5000 Å, and the source-drain metal layer is made from copper.

14. The manufacturing method according to claim 1, wherein the first semiconductor layer directly contacts the gate insulation layer, the second semiconductor layer contacts the first barrier layer, the first barrier layer contacts the second barrier layer, and the second barrier layer contacts the drain and the source.

15. The manufacturing method according to claim 1, wherein the gate has a thickness of 500-4000 Å, and the gate is made from Cr, W, Ti, Ta, Mo, Al and Cu or alloys thereof, and the gate is in a form of a single layer or multiple layers.

16. The manufacturing method according to claim 1, wherein the passivation layer has a thickness of 2000-5000 Å, the passivation layer is made from an oxide, a nitride or an oxynitride, and the passivation layer is in a form of a single layer or multiple layers.

17. The manufacturing method according to claim 1, wherein the transparent conductive layer has a thickness of 300-1500 Å, and the transparent conductive layer is made from indium tin oxide ITO or indium zinc oxide IZO.

18. An array substrate, wherein the array substrate is manufactured by the manufacturing method according to claim 1 the array substrate comprises a base substrate, and a gate, a gate insulation layer, a first semiconductor layer, a second semiconductor layer, a first barrier layer, a second barrier layer, a source-drain metal layer, a passivation layer and a pixel electrode disposed in sequence on the base substrate, the source-drain metal layer comprises a source and a drain, and a channel region is between the source and the drain;
each of the first semiconductor layer and the second semiconductor layer is a metal oxide semiconductor layer, and an oxygen content of the first semiconductor layer is lower than an oxygen content of the second semiconductor layer;
the first barrier layer is made from titanium metal nitride, and the second barrier layer is made from titanium or titanium alloy; and
the passivation layer has a conductive via thereon, and the pixel electrode is communicated with the drain through the conductive via.

19. The manufacturing method according to claim 2, wherein each of the first semiconductor layer and the second semiconductor layer is a metal oxide semiconductor layer, comprising amorphous indium gallium zinc oxide; and
an oxygen content of the first semiconductor layer is lower than an oxygen content of the second semiconductor layer.

20. The manufacturing method according to claim 3, wherein each of the first semiconductor layer and the second semiconductor layer is a metal oxide semiconductor layer, comprising amorphous indium gallium zinc oxide; and
an oxygen content of the first semiconductor layer is lower than an oxygen content of the second semiconductor layer.
